(19) United States
(12) Patent Application Publication
(10) Pub. No.: US 2004/0263272 A1
(43) Pub. Date: Dec. 30, 2004

(54) Enhanced single-supply low-voltage circuits and methods thereof

(76) Inventors: Ashoke Ravi, Hillsboro, OR (US); Krishnamurthy Soumyanath, Portland, OR (US); Gerhard Schrom, Hillsboro, OR (US); Gaurab Banerjee, Hillsboro, OR (US)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/608,554

(22) Filed: Jun. 30, 2003

(51) Int. Cl. H03B 1/00

(52) U.S. Cl. 331/177 V

(57) ABSTRACT

Briefly, devices and methods which may be used in conjunction with a Complementary Metal-Oxide Semiconductor (CMOS) process. Exemplary embodiments of the invention may provide an enhanced charge-pump circuit with gain compensation, an enhanced varactor with wide tuning range, and/or enhanced Phase-Lock Loop (PLL) circuits, which may be used, for example, within various oscillators and/or wireless communication devices.

### BACKGROUND OF THE INVENTION

Some standards of wireless communications include stringent phase-noise specifications, which require use of Inductance Capacitance (LC) oscillators in wireless communication devices. Unfortunately, LC oscillators and/or Voltage Controlled Oscillators (VCOs) can be tuned only over a relatively narrow range of frequencies. Furthermore, even within their tunable range, the transfer characteristics of LC oscillators may be significantly non-linear, specifically, the slope of a transfer function, e.g., frequency versus control voltage, of the VCO may “flatten” when the control voltage is close to either an upper or a lower limit of an effective range. As a result, in some closed loop systems, for example, in some Phase-Locked Loop (PLL) synthesizers and/or frequency synthesizers, in order to meet jitter/phase-noise specifications and/or settling time requirements, the tuning range of the VCO may be restricted to a relatively narrow region, which is substantially linear and sufficiently steep, of the transfer function. In some closed loop systems, this narrow range of frequencies may not cover the entire spectrum used by a communication standard.

In some PLL synthesizers and/or frequency synthesizers, adaptively compensating for the drop-off in VCO gain in other loop components may extend the tunable range of frequencies to nearly the full range of the VCO, while maintaining settling time, phase-noise and attenuation performance requirements in a single-supply low-voltage digital Complementary Metal-Oxide Semiconductor (CMOS) process, and without significantly impairing an average power dissipation. However, this scheme may result in higher charge-pump currents near the two extremes of the control voltage range, where the current delivery capability of charge-pump circuits may degrade. Therefore, the tuning range expansion is restricted by this drop-off in the charge-pump currents at the top and bottom ends of the control voltage range.

In some LC oscillators, a tank capacitor may be used as the tunable element. In some closed loop operations, for example, in some PLL synthesizers and/or in some frequency synthesizers, stability considerations may dictate a monotonic capacitance-voltage (C-V) characteristic. Thus, the tuning range of conventional diode varactors and/or Metal-Oxide-Semiconductor Field Effect Transistor (MOSFET) varactors, when operated by a single low-voltage supply process, may be significantly limited.

Some conventional oscillators use single ended tuning, which may be prone to noise coupling from a substrate and/or from a power supply. Additionally or alternatively, some conventional oscillators use diodes as the tunable element; however, the need to keep the diodes constantly reverse-biased may limit the tunable range of the oscillator and may require the use of an additional larger power supply. In some conventional oscillators using Metal-Oxide-Semiconductor (MOS) varactors as the tunable element, the non-monotonicity of the C-V characteristics may limit the usable frequency range to significantly below the supply voltages.

Gate overdrive may be defined as V_{gs}-Vₜ, wherein V_{gs} is a gate-to-source voltage, and Vₜ is a threshold voltage required to activate, i.e., “turn on” a transistor. Some VCOs may include a charge-pump circuit, which may include switch transistors. The gate overdrive of the switch transistors may be very large, for example, when either “up” or “down” signals are active. In a conventional charge-pump circuit, the output may be directly connected to the drain of the switching transistors, and thus the current delivery of the charge-pump circuit may be reduced because the device may fall out of saturation.

Furthermore, some VCOs may include a circuit to compensate for a drop in VCO gain. If such a compensating circuit is used, e.g., to widen the range of frequencies over which a PLL synthesizer and/or a frequency synthesizer may lock, while trying to maintain settling time and/or phase-noise and reference frequency attenuation, then the degradation in current delivery capability of the charge-pump may cause the compensating circuit to fail.

### BRIEF DESCRIPTION OF THE DRAWINGS

The subject matter regarded as the invention is particularly pointed out and distinctly claimed in the concluding portion of the specification. The invention, however, both as to organization and method of operation, together with features and advantages thereof, may best be understood by reference to the following detailed description when read with the accompanied drawings in which:

FIG. 1 is a schematic illustration of a wireless communications device incorporating an oscillator in accordance with an exemplary embodiment of the invention;

FIG. 2 is a schematic illustration of a graph depicting capacitance as a function of control voltage of a varactor according to exemplary embodiments of the invention, compared to the capacitance as a function of control voltage of a conventional varactor;

FIG. 3 is a schematic illustration of a Negative-charged-carrier MOS (NMOS) varactor in accordance with one exemplary embodiment of the invention;

FIG. 4 is a schematic illustration of a Positive-charged-carrier MOS (PMOS) varactor in accordance with another exemplary embodiment of the invention;

FIG. 5 is a schematic illustration of an accumulation mode NMOS varactor in accordance with a further exemplary embodiment of the invention;

FIG. 6 is a schematic block illustration of a fully-differential wide-tuning-range Phase-Locked Loop (PLL) circuit in accordance with exemplary embodiments of the invention;

FIG. 7 is a schematic illustration of a Voltage Controlled Oscillator (VCO) circuit that may be used in the circuit of FIG. 6 in some exemplary embodiments of the invention;

FIG. 8 is a schematic illustration of a low-dropout charge-pump circuit with gain compensation in accordance with exemplary embodiments of the invention;

FIG. 9 is a schematic illustration of a multiplexer that may be used in the circuit of FIG. 8 in some exemplary embodiments of the invention;

FIG. 10 is a schematic illustration of an enhanced charge-pump circuit with low drop-out gain compensation in accordance with exemplary embodiments of the invention;

FIG. 11 is a schematic illustration of a charge-pump circuit using mirror switch-off with enhanced gain compensation in accordance with exemplary embodiments of the invention;

FIG. 12 is a schematic illustration of a graph depicting gain in accordance with exemplary embodiments of the invention; and

FIG. 13 is a schematic flow chart of a method of tuning an oscillator in accordance with an exemplary embodiment of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However, it will be understood by those of ordinary skill in the art that the invention may be practiced without these specific details. In other instances, well-known methods, procedures, components, units and/or circuits have not been described in detail so as not to obscure the invention.

It should be understood that embodiments of the invention may be used in a variety of applications. Although the invention is not limited in this respect, embodiments of the invention may be used in many apparatuses, for example, a transmitter, a receiver, a transceiver, a transmitter-receiver, and/or a wireless communication device. Wireless communication devices intended to be included within the scope of the invention include, by way of example only, cellular radio-telephone communication systems, cellular telephones, wireless telephones, cordless telephones, Wireless Local Area Networks (WLAN) and/or devices operating in accordance with the existing 802.11a, 802.11b, 802.11g, 802.11n and/or future versions of the above standards, Personal Area Networks (PAN), Wireless PAN (WPAN), units and/or devices which are part of the above WLAN and/or PAN and/or WPAN networks, one way and/or two-way radio communication systems, one-way pagers, two-way pagers, Personal Communication Systems (PCS) devices, a Portable Digital Assistant (PDA) device which incorporates a wireless communications device, and the like.

By way of example, types of cellular radio-telephone communication systems intended to be within the scope of the invention include, although not limited to, Direct Sequence—Code Division Multiple Access (DS-CDMA) cellular radio-telephone communication systems, Global System for Mobile Communications (GSM) cellular radio-telephone systems, North American Digital Cellular (NADC) cellular radio-telephone systems, Time Division Multiple Access (TDMA) systems, Extended-TDMA (E-TDMA) cellular radio-telephone systems, Wideband CDMA (WCDMA) systems, General Packet Radio Service (GPRS) systems, Enhanced Data for GSM Evolution (EDGE) systems, 3G systems, 3.5G systems, 4G systems, communication devices using various frequencies and/or range of frequencies for reception and/or transmission, communication devices using 2.4 Gigahertz frequency, communication devices using 5.2 Gigahertz frequency, communication devices using 24 Gigahertz frequency, communication devices using an Industrial Scientific Medical (ISM) band and/or several ISM bands, and other existing and/or future versions of the above.

Exemplary embodiments of the invention provide circuits and methods to improve the tuning and/or locking range of tunable oscillators. For example, some embodiments of the invention may provide circuits for wide-range tuning of an oscillator, suitable for use, for example, with high performance, low power, Radio Frequency (RF) transceivers using low cost, low voltage, digital single-supply Complementary Metal-Oxide Semiconductor (CMOS) processes. Some embodiments of the invention may provide high-performance, low-power RF band synthesizers, using low-cost, low-voltage digital CMOS processes, and/or using a single supply voltage. Additionally or alternatively, some embodiments of the invention may provide methods and circuits to enable adaptive gain compensation in a PLL synthesizer and/or a frequency synthesizer.

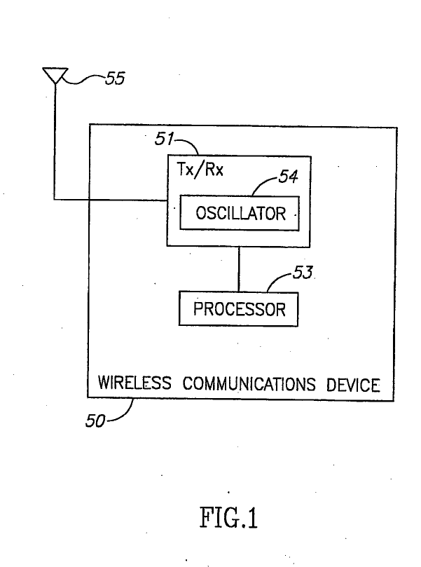

FIG. 1 schematically illustrates a wireless communications device 50 incorporating an oscillator 54 in accordance with some exemplary embodiments of the invention. In addition to oscillator 54, wireless communications device 50 may include a transceiver 51, a processor 53, and an antenna 55.

Processor 53 may include, for example, a Central Processing Unit (CPU), a Digital Signal Processor ASP), a chip, a microchip, or any other suitable multi-purpose or specific processor or micro-processor.

Antenna 55 may include an internal and/or external Radio Frequency (RF) antenna, for example, a dipole antenna and/or any other type of antenna suitable for sending and receiving signals to enable device 50 to communicate with a desired communication network.

Transceiver 51 may be implemented, for example, using one or more units performing separate or integrated functions, for example, in the form of separate transmitter and receiver units or in the form of a single transceiver unit or a single transmitter-receiver unit. Transceiver 51 may include oscillator 54, or several oscillators or oscillating circuits, e.g., one or more oscillators similar to oscillator 54.

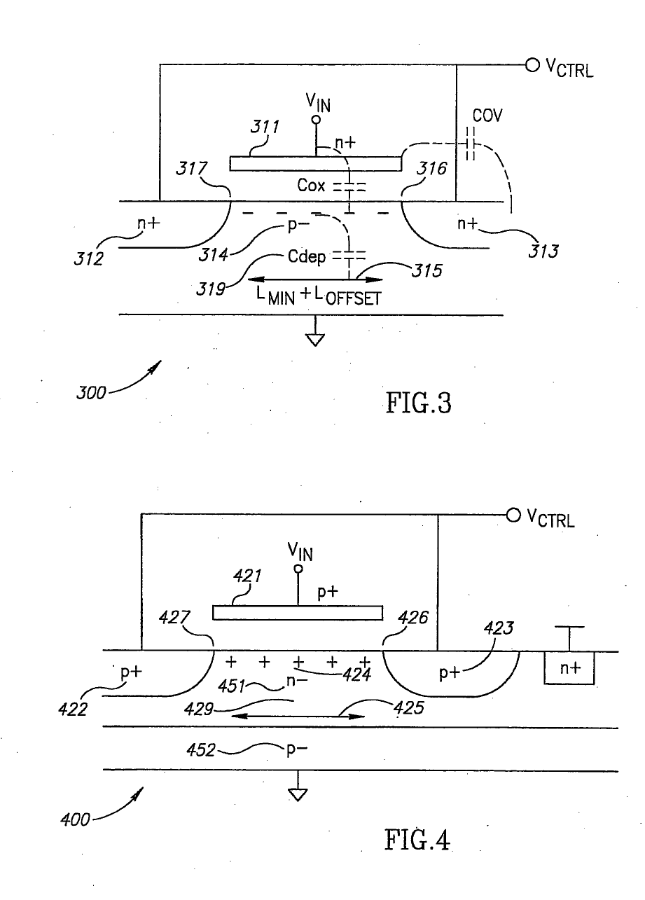

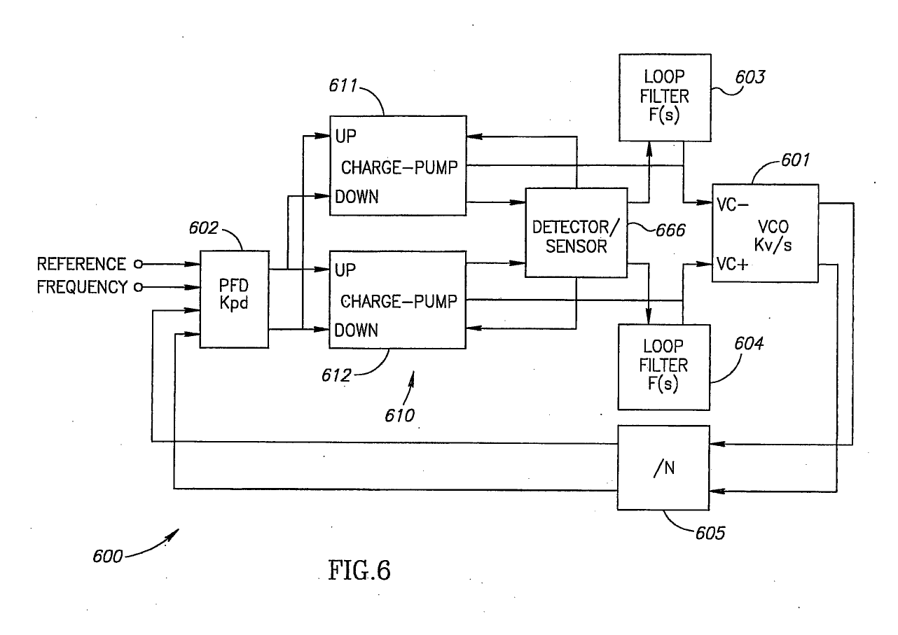

Oscillator 54 may include an oscillator, an oscillating circuit and/or other suitable components in accordance with embodiments of the invention. In some embodiments, oscillator 54 may include a varactor, for example, one or more of the varactors described below with reference to FIGS. 3 to 5. Additionally or alternatively, in some embodiments, oscillator 54 may include one or more of the circuits described below with reference to FIGS. 6 to 11. It will be appreciated by persons skilled in the art that embodiments of the invention may be implemented in conjunction with other types of varactors and/or circuits, as well as with other suitable existing or future circuit components.

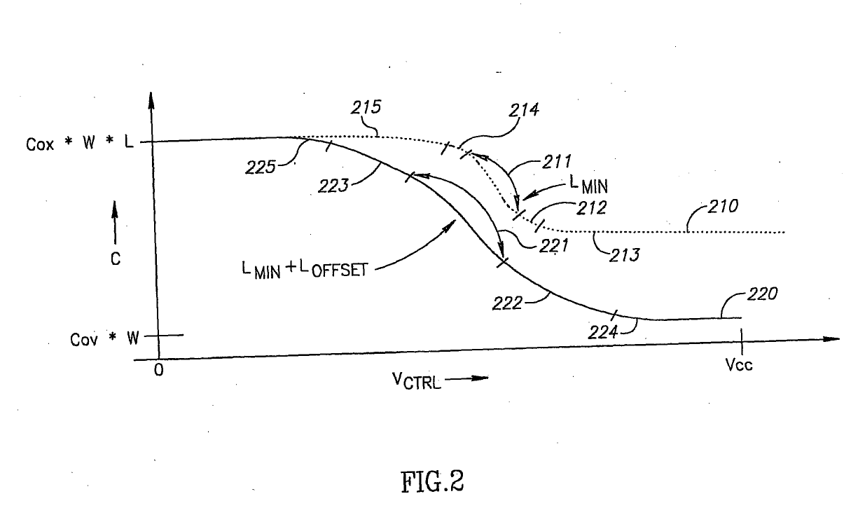

FIG. 2 schematically illustrates graphs depicting an expansion of a raw tuning range of a varactor in accordance with an exemplary embodiment of the invention compared to a raw tuning range of a conventional varactor. Curve 220 depicts capacitance in response to applied voltage (“CV characteristic”) of a varactor in accordance with an exemplary embodiment of the invention. Curve 210 depicts the CV characteristic of a conventional varactor. As illustrated schematically in FIG. 2, curve 320 may include a peak-gain region (“linear range”) 221, two fading-slope regions, 222 and 223, and two substantially flat regions, 224 and 225. Curve 210 may include a peak-gain region (“linear range”) 211, two fading-gain regions, 212 and 213, and two substantially flat regions, 214 and 215. It is noted that the phrase “linear range” is used herein in reference to peak-gain regions 221 and 211 for convenience only, and may include, for example, a generally monotonic region with a significant slope of the CV characteristic function.

In accordance with some exemplary embodiments of the invention, linear range 221 extends over a significantly wider range of the applied control voltage compared to the corresponding linear range 211 of a conventional varactor. Additionally or alternatively, in some exemplary embodiments of the invention, fading-gain regions 222 and 223 may extend over wider ranges, and may represent more gradual fading, compared to the corresponding fading-gain regions 212 and 213 of a conventional varactor.

It will be appreciated by persons skilled in the art that the expanded linear range of varactors according to exemplary embodiments of some aspects of the invention, as described in detail below, may allow a significant expansion of the tuning and/or locking range of oscillators and/or synthesizers incorporating such varactors. Furthermore, as described in detail below, exemplary embodiments of some aspects of the invention may allow expanding the tuning range of varactors beyond their linear ranges, e.g., utilizing at least a significant portion of the fading-gain regions, which are not utilized in conventional varactors.

In some exemplary embodiment of the invention, the fading gain region may be defined as regions outside the linear range in which the VC curve slope (dC/dV_{cntl}) is, for example, at least 10% to 30% of a peak-gain of the VC curve. The peak-gain of the VC curve may be defined as the average slope (dC/dV_{cntl}) in the linear range. It is noted that these percentage values are presented for exemplary purposes only; embodiments of the invention are not limited in this regard, and various other values, slope values, percentage values and/or curve shapes may be used with various embodiments in accordance with the invention.

In accordance with some embodiments of the invention, a Metal-Oxide Semiconductor (MOS) device may be confined to operate in either an inversion region, e.g., negative carriers in a p− substrate, or an accumulation region, e.g., negative carriers in an n− substrate, without suffering from a monotonicity problem in the Capacitance Voltage (CV) characteristic. In some embodiments, this may be accomplished, for example, using a varactor as illustrated schematically in FIGS. 3 to 5.

FIG. 3 schematically illustrates a Negative-charged-carrier MOS (NMOS) varactor 300 in accordance with an exemplary embodiment of the invention. Varactor 300 may include, for example, an n+ gate 311 and a p− channel 314 between two n+ regions, 312 and 313. An overlap area 316 may be defined between gate 311 and n+ region 313, and an overlap area 317 may be defined between gate 311 and n+ region 312. Arrow 315 indicates the length, L, of channel 314 between n+ regions 312 and 313. Varactor 300 may further include a substrate 319, for example, a silicon layer.

The length, L, of channel 314 may be equal to the sum of Lₘᵢₙ, which is defined herein as the minimum operable/feasible channel length in a given technology generation, and L_{offset}, which is an additional offset length in accordance with embodiments of the invention. For example, in current technologies, Lₘᵢₙ may be between approximately 0.13 micrometer and 0.25 micrometer. It will be appreciated by persons skilled in the art that other technologies may have other values of Lₘᵢₙ, for example, future technologies may have lower values of Lₘᵢₙ, and that the scope of the invention is in no way limited to specific values of Lₘᵢₙ. In an exemplary embodiment, L_{offset} may be equal to, for example, between 50% and 100% of Lₘᵢₙ. It is noted that these percentage values are presented for exemplary purposes only; embodiments of the invention are not limited in this regard, and various other values or percentage values may be used with various embodiments in accordance with the invention.

Analyzing the capacitance and voltage in different regions of varactor 300 as a function of the dimensions of varactor 300, in a lower control voltage range of V_{cntl}<Vᵢₙ−Vₜ, wherein V_{cntl} is the control voltage of varactor 300, Vᵢₙ is the voltage of gate 311 and Vₜ is a threshold voltage of varactor 300, the following equation holds:

Cᵢₙ=Cₒₓ*W*L (1)

wherein W is the width of channel 314, Cᵢₙ is the capacitance of varactor 300, and Cₒₓ is the oxigenizer capacitance of gate 311.

Similarly, in a higher control voltage range of V_{cntl}>Vᵢₙ−Vₜ, the following equation holds:

Cᵢₙ=(Cₒᵥ*W)+W*L*(Cₒₓ*C_{dep})/(Cₒₓ+C_{dep}) (2)

wherein C_{dep} is depletion capacitance of varactor 300 and Cₒᵥ is the capacitance resulting from overlap areas 316 and 317.

However, in accordance with embodiments of the invention, if V_{ctrl} is significantly larger than (Vᵢₙ−Vₜ), i.e., if V_{ctrl}>>Vᵢₙ−Vₜ, then the following equation holds:

Cᵢₙ˜Cₒᵥ*W (3)

such that the capacitance Cᵢₙ of varactor 300 may be substantially proportional to Cₒᵥ and to W, yet substantially independent of L.

It is noted that in some exemplary embodiments, varactor 300 may operate in inversion, for example, such that an n− channel exists in a p− substrate.

FIG. 4 schematically illustrates a Positive-charged-carrier MOS (PMOS) varactor 400 in accordance with an exemplary embodiment of the invention. Varactor 400 may include, for example, a p+ gate 421 and an n− channel 424 between two p+ regions, 422 and 423. An overlap area 426 may be defined between gate 421 and p+ region 423, and an overlap area 427 may be defined between gate 421 and p+ region 422. Arrow 425 indicated the length, L, of channel 424 between p+ regions 422 and 423. Varactor 400 may further include an n− region 451, a p+ region 452, an n+ region 428, and a substrate 429, for example, a silicon layer.

As in the previous exemplary embodiment, the length, L, of channel 424 may be equal to the sum of Lₘᵢₙ, which is the minimum operable/feasible channel length in a given technology generation, and L_{offset}, which is an additional offset length in accordance with embodiments of the invention. For example, in current technologies, Lₘᵢₙ may be between approximately 0.13 micrometer and 0.25 micrometer. It will be appreciated by persons skilled in the art that other technologies may have other values of Lₘᵢₙ, for example, future technologies may have lower values of Lₘᵢₙ, and that the scope of the invention is in no way limited to specific values of Lₘᵢₙ. In an exemplary embodiment, L_{offset} may be equal to, for example, between 50% and 100% of Lₘᵢₙ. It is noted that these percentage values are presented for exemplary purposes only; embodiments of the invention are not limited in this regard, and various other values or percentage values may be used with various embodiments in accordance with the invention.

Analyzing the capacitance and voltage in different regions of varactor 400 as a function of the dimensions of varactor 400, in a higher control voltage range of V_{ctrl}>Vᵢₙ−|Vₜ|, wherein V_{ctrl} is the control voltage of varactor 400, Vᵢₙ is the voltage of gate 421 and Vₜ is a threshold voltage of varactor 400, the following equation holds:

Cᵢₙ=Cₒₓ*W*L (4)

wherein W is the width of channel 424, Cᵢₙ is the capacitance of varactor 400, and Cₒₓ is the oxigenizer capacitance of gate 421.

Similarly, in a lower control voltage range of V_{ctrl}<Vᵢₙ−|Vₜ|, the following equation holds:

Cᵢₙ=(Cₒᵥ*W)+W*L*(Cₒₓ*C_{dep})/(Cₒₓ+C_{dep}) (5)

wherein C_{dep} is depletion capacitance of varactor 400 and Cₒᵥ is the capacitance resulting from overlap areas 426 and 427.

However, in accordance with embodiments of the invention, if V_{ctrl} is significantly smaller than (Vᵢₙ−|Vₜ|), i.e., if V_{ctrl}<<Vᵢₙ−|Vₜ|, then the following equation holds:

Cᵢₙ˜Cₒᵥ*W (6)

such that the capacitance Cᵢₙ of varactor 400 may be substantially proportional to Cₒᵥ and to W, yet substantially independent of L.

It is noted that in some embodiments, varactor 400 may operate in inversion, for example, such that a p− channel exists in an n− substrate. To achieve this functionality, varactor 400 may be modified in accordance with methods as are known in the art.

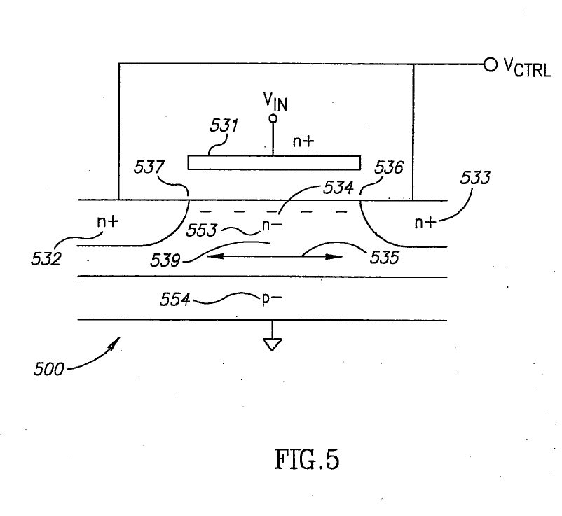

FIG. 5 schematically illustrates an accumulation-mode Negative-charged-carrier MOS (NMOS) varactor 500 in accordance with an exemplary embodiment of the invention. Varactor 500 may include, for example, a n+ gate 531 and a channel 534 between two n+ regions, 532 and 533. An overlap area 536 may be defined between gate 531 and n+ region 533, and an overlap area 537 may be defined between gate 531 and n+ region 532. Arrow 535 indicates the length, L, of channel 534 between n+ regions 532 and 533. Varactor 500 may further include a n− region 553, a p− region 554, and a substrate 539, for example, a silicon layer.

As in the previous exemplary embodiments, the length, L, of channel 534 may be equal to the sum of Lₘᵢₙ, which is the minimum operable/feasible channel length in a given technology generation, and L_{offset}, which is an additional offset length in accordance with embodiments of the invention. For example, in current technologies, Lₘᵢₙ may be between approximately 0.13 micrometer and 0.25 micrometer. It will be appreciated by persons skilled in the art that other technologies may have other values of Lₘᵢₙ, for example, future technologies may have lower values of Lₘᵢₙ, and that the scope of the invention is in no way limited to specific values of Lₘᵢₙ. In an exemplary embodiment, L_{offset} may be equal to, for example, between 50% and 100% of Lₘᵢₙ. It is noted that these percentage values are presented for exemplary purposes only; embodiments of the invention are not limited in this regard, and various other values or percentage values may be used with various embodiments in accordance with the invention.

Analyzing the capacitance and voltage in different regions of varactor 500 as a function of the dimensions of varactor 500, in a higher range of the control voltage, e.g., for the range of V_{cntl}>Vᵢₙ−|Vₜ|, wherein V_{ctrl} is the control voltage of varactor 500, Vᵢₙ is the voltage of gate 531 and Vₜ is a threshold voltage of varactor 500, the following equation holds:

Cᵢₙ=Cₒₓ*W*L (7)

wherein W is the width of channel 534, Cᵢₙ is the capacitance of varactor 500, and Cₒₓ is the oxigenizer capacitance of gate 531.

Similarly, in a lower range of the control voltage, e.g., for the range of V_{cntl}<Vᵢₙ−|Vₜ|, the following equation holds:

Cᵢₙ=(Cₒᵥ*W)+W*L*(Cₒₓ*C_{dep})/(Cₒₓ+C_{dep}) (8)

wherein C_{dep} is depletion capacitance of varactor 500 and Cₒₓ is the capacitance resulting from overlap areas 536 and 537.

However, in accordance with embodiments of the invention, if V_{ctrl} is much smaller than (Vᵢₙ−|Vₜ|), i.e., if V_{ctrl}<<Vᵢₙ−|Vₜ|, then the following equation holds:

Cᵢₙ˜Cₒᵥ*W (9)

such that the capacitance Cᵢₙ of varactor 500 may be substantially proportional to Cₒᵥ and to W, yet substantially independent of L.

In exemplary embodiments of the invention, as a result of the increased length of the channels of varactors 300, 400 and/or 500 as described above, the maximum capacitance of varactors 300, 400 and/or 500 may be equal to Cₒₓ*W*L, wherein L=Lₘᵢₙ+L_{offset}, while their minimum capacitance may be equal to Cₒᵥ*W. This may allow, for example, achieving a wider tuning range and/or improved locking ability and/or improved frequency acquisition in circuits, oscillators, synthesizers and/or devices incorporating a varactor in accordance with embodiments of the invention.

In an exemplary embodiment, varactors 300, 400 and/or 500 may be used in an oscillator, for example, in oscillator 54 of FIG. 1. It will be appreciated by persons skilled in the art that the wider raw tuning range and/or the wider capacitance of varactors according to embodiments of the invention results in a wider tuning range of the frequency generated by oscillator 54.

The following additional description of the operation of varactor 300 is presented for exemplary purposes; a similar description may apply to other suitable varactors in accordance with embodiments of the invention, for example, to varactor 400 and/or 500.

In some implementations of varactor 300, if the voltage of gate 311 is higher than the bulk voltage (i.e., the voltage of substrate 319) by the threshold voltage of varactor 300, then an inversion layer may form at substrate 319 below gate 311. The inversion layer may have a voltage equal to the voltage of regions 312 and 313 (“source/drain voltage”), and may shield the bulk (i.e., substrate 319) from the charge of gate 311. In such case, the input capacitance Cᵢₙ may be equal to Cₒₓ*W*L, because the conditions for Equation 1 are met. If the source/drain voltage is higher than the voltage of gate 311, then the inversion layer may not form, even though gate 311 may have a threshold voltage higher than substrate 319. In such case, the charge of gate 311 may be supported by, for example, depleting the bulk, and this may form the depletion capacitance, C_{dep}.

In some implementations of varactor 300, a series sum of the capacitance Cₒₓ and C_{dep} of varactor 300 may asymptotically approach zero. The overlap capacitance between gate 311 and regions 312 and 313, i.e., source/drain terminals of varactor 300, may remain unchanged, and the minimum capacitance may be proportional or equal to Cₒᵥ*W, in accordance with Equation 3.

In some embodiments, the width, W, of varactor 300 may be adjusted, for example, to obtain a desired maximum and/or minimum capacitance of varactor 300. It is noted that in some embodiments, a relatively longer varactor 300 may have a relatively smaller minimum capacitance for a specified maximum capacitance.

In some embodiments, a relatively long varactor 300 may result in degradation in series resistance and thus in phase-noise and operating frequency. However, a relatively low quality (Q) factor required for some on-chip inductors may allow a certain margin of increase in series resistance of varactor 300; the increase may be, for example, by 50% to 100%. It is noted that these percentage values are presented for exemplary purposes only; embodiments of the invention are not limited in this regard, and various other values or percentage values may be used with various embodiments in accordance with the invention. Therefore, in some embodiments, the offset length used in varactor 300, L_{offset}, may be such that total length of varactor 300, and thus (Cₘₐₓ/Cₘᵢₙ), is maximized but is less than a length that may begin to degrade the quality of varactor 300, e.g., due to increased series resistance, below a minimum specified value.

Additionally or alternatively, embodiments of the invention may allow better locking and/or tuning and/or frequency acquisition of oscillators and/or synthesizers, particularly in the fading-gain regions of the CV characteristic. Referring to the graph of FIG. 2, in some exemplary embodiments, fading-gain regions 222 and 223 may extend over a wider range, and may represent more gradual fading, compared to the corresponding fading-gain regions 212 and 213 of a conventional varactor.

In accordance with exemplary embodiments of the invention, the gain of a VCO, denoted K_{V}, may be measured, sensed and/or calculated, directly and/or indirectly. In some embodiments, the gain may be measured using a dedicated sensor/detector unit, as described below, which may calculate loop-gain based on a control voltage.

Based on the gain of the VCO, the gain of a charge-pump, denoted K_{CP}, which may be related to the capacitance of the charge-pump, may be set, adjusted and/or modified. In some embodiments, such adjustment may be performed smoothly and/or substantially continuously. Some embodiments may improve the total gain of a circuit, and/or may allow better tuning and/or locking of frequencies, for example, in relation to capacitance of fading-gain regions in the graph of FIG. 2.

FIG. 13 is a schematic flow chart of a method of tuning an oscillator in accordance with exemplary embodiments of the invention. As indicated at block 1310, the gain of a VCO may be sensed. This may be performed directly and/or indirectly, for example, by measuring and/or calculating the gain of the VCO. It is noted that in alternate embodiments, the gain of another component, a group of components or a portion of the oscillation circuit may be sensed and may be used as a basis for further tuning, in addition to or instead of the gain of the VCO.

As indicated at block 1320, a charge-pump may be tuned. This may be performed, for example, based on the gain of the VCO. For example, if the gain of the VCO is reduced, e.g., in the fading gain areas, then the gain of the charge-pump may be increased by the amount required to increase the over-all gain back to a desired range, e.g., between 50% and 100% of the peak gain. It is noted that these percentage values are presented for exemplary purposes only; embodiments of the invention are not limited in this regard, and various other values or percentage values may be used with various embodiments in accordance with the invention.

Therefore, by appropriately adjusting the gain of the charge-pump, the over-all gain of the oscillator may be maintained at the desired range. In some embodiments, this may allow improved tuning, locking and/or acquisition of frequencies.

It is noted that the above operations may be performed, for example, periodically, repeatedly, continuously, or substantially continuously. In some embodiments, additional and/or alternative operations may be used, for example, to detect a property related to the gain of the VCO, other gain-contributing components of the oscillator circuit, or the over-all gain of the oscillator circuit, and to tune the gain of a charge-pump based on the detected property.

FIG. 6 schematically illustrates a fully-differential wide-tuning-range Phase-Locked Loop (PLL) tuning circuit 600 in accordance with an exemplary embodiment of the invention. Circuit 600 may be used and/or included, for example, within oscillator 54 of FIG. 1. Circuit 600 may include, for example, a Voltage Controlled Oscillator (VCO) 601, a Phase-Frequency Detector (PFD) 602, a loop filter 603, a loop filter 604, a divider 605, a charge-pump unit 610, and an optional sensor/detector 666. Tuning circuit 600 may also be referred to herein as gain tuner, gain controller, gain tuning circuit, or charge-pump gain tuner.

In some embodiments, charge-pump unit 610 may be fully differential. For example, in some embodiments, charge-pump unit 610 may include two replica circuits or two similar charge-pump circuits, with swapped “up” and “down” inputs, e.g., charge-pump sub-units 611 and 612, respectively.

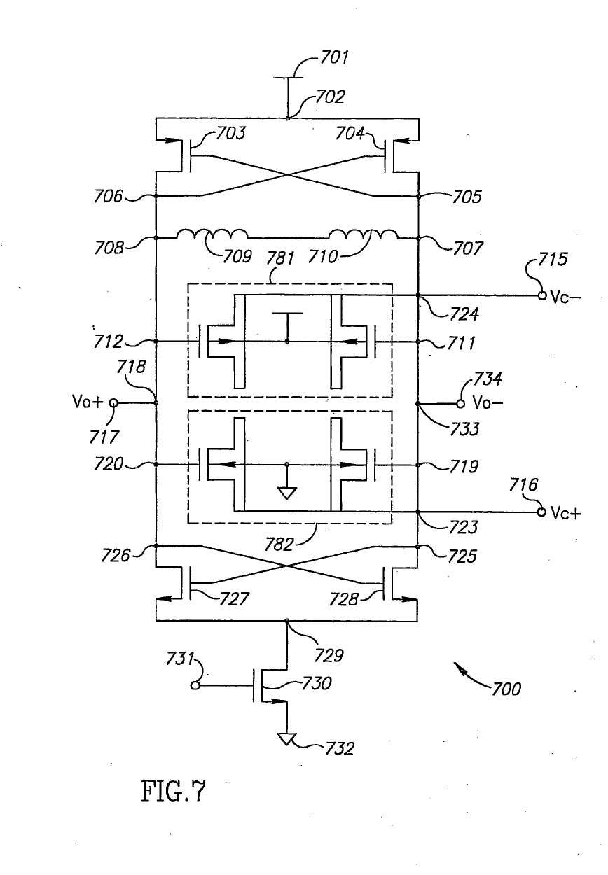

VCO 601 may include, for example, a differential circuit. In some embodiments, VCO 601 may include circuit 700 of FIG. 7.

In some embodiments, VCO 601 may provide a VCO gain denoted K_{V}, and charge-pump unit 610 may provide a gain denoted K_{CP}. In accordance with exemplary embodiments of the invention, K_{CP} may be tunable, modifiable and/or adjustable. Furthermore, in some embodiments, K_{CP} may be tuned, adjusted and/or modified in relation to a detected value of K_{V}.

Divider 605 may divide the frequency of a signal or signals received from VCO 601. Dividing the signals may allow, for example, more accurate comparisons of frequency and/or phase, and/or may allow using a wider variety of units or components to perform such comparison operations.

PFD 602 may measure and/or compare phase and/or frequency of signals. For example, PFD 602 may compare an output signal received from divider 605, with a reference signal, and may produce an “up” or a “down” signal based on their phase difference and/or frequency difference. In some embodiments, PFD 602 may modify and/or correct the phases of the signals within circuit 600; furthermore, when circuit 600 is “locked”, PFD 602 may further fine-tune the frequency of circuit 600. It is noted that in some embodiments, PFD 602 may include a circuit different from the exemplary embodiments shown and described herein.

In some embodiments, circuit 600 may optionally include a sensor/detector 666, to sense, detect, measure and/or calculate the gain of VCO 601, to perform gain compensation, and/or to change a property and/or capacitance and/or gain of charge-pump unit 610.

In an exemplary embodiment, sensor/detector 666 may include a transconductor, or another suitable combination of voltage-to-current or current-to-voltage converters. In some embodiments, a control voltage may represent the gain of VCO 601; sensor/detector may measure the control voltage, calculate the gain based on the control voltage, and operate charge-pump unit 610, for example, to modify current.

It is noted that in some embodiments, one or more of the components of circuit 600 may be fully differential. This increase the noise immunity of circuit 600 and/or of a device incorporating circuit 600, for example, a PLL synthesizer, a frequency synthesizer, oscillator 54 of FIG. 1, or other suitable devices.

In some embodiments, charge-pump sub-units 611 and 612 may be merged into a circuit with shared current sources; however, since the current source would be mostly off, the effect of “turn-on” transients of charge-pumps 611 and 612 might hinder locking when the “up” and “down” pulse widths are reduced near the steady state. This potential result may be mitigated, for example, using a leakage current path, which may be selectively turned-on only near lock. In some embodiments, using a charge-pump unit 610 with a leak current path may allow a faster locking process or may expedite a locking process.

FIG. 7 schematically illustrates a VCO circuit 700 in accordance with exemplary embodiments of the invention. Circuit 700 may be included, for example, within oscillator 54 of FIG. 1. Circuit 700 as schematically illustrated in FIG. 7 may be an exemplary implementation of VCO 601 of FIG. 6.

Within circuit 700, a voltage supply 701 may be connected to a node 702. Node 702 may be connected to a source terminal of a transistor 703, a node 706 may be connected to a drain terminal of transistor 703, and a node 705 may be connected to a gate terminal of transistor 703. Node 706 may be connected to a gate terminal of transistor 704, node 702 may be connected to a source terminal of transistor 704, and node 705 may be connected to a drain terminal of transistor 404.

Node 706 may be connected to a node 708, and node 705 may be connected to a node 707. In some embodiments, inductors 709 and 710 may be connected in series between node 707 and node 708. Node 708 may be connected to a node 712, and node 707 may be connected to a node 711. A sub-circuit 781 may be connected between node 711 and node 712.

In an exemplary embodiment of the invention, sub-circuit 781 may include a transistor 783, a transistor 784, and a voltage supply 785. In some embodiments, sub-circuit 781 may include, for example, one or more differential varactors. In some embodiments, sub-circuit 781 may include, for example, one or more PMOS varactors, e.g., one or more PMOS varactors similar to varactor 400 of FIG. 4.

Node 711 may be connected to a node 733, and node 712 may be connected to a node 718. Node 718 may be connected to a node 717 and to a node 720. Node 733 may be connected to a node 734 and to a node 719. Node 717 may be a positive output voltage, and node 734 may be a negative output voltage. A sub-circuit 782 may be connected between node 719 and node 720.

In an exemplary embodiment of the invention, sub-circuit 782 may include a transistor 786, a transistor 787, and a sink 788. In some embodiments, sub-circuit 782 may include, for example, one or more differential varactors. In some embodiments, sub-circuit 782 may include, for example, one or more NMOS varactors, e.g., one or more NMOS varactors similar to varactor 300 of FIG. 3.

Node 715 may be a negative control voltage, and a node 716 may be a positive control voltage.

Node 720 may be connected to a node 726, and node 719 may be connected to a node 725. Node 725 may be connected to a gate terminal of a transistor 727, and node 726 may be connected to a gate terminal of a transistor 728. Node 726 may be connected to a drain terminal of transistor 727, and node 725 may be connected to a drain terminal of transistor 728. A node 729 may be connected to a source terminal of transistor 727 and to a source terminal of transistor 728. A drain terminal of a transistor 730 may be connected to node 729, and a source terminal of transistor 730 may be connected to a sink 732. A gate terminal of transistor 730 may be connected to node 731, which may provide bias for current source.

It is noted that transistors 703, 704, 727 and/or 728 may include negative impedance circuits, for example, to cancel resistive losses which may occur due to inductors 709 and 710.

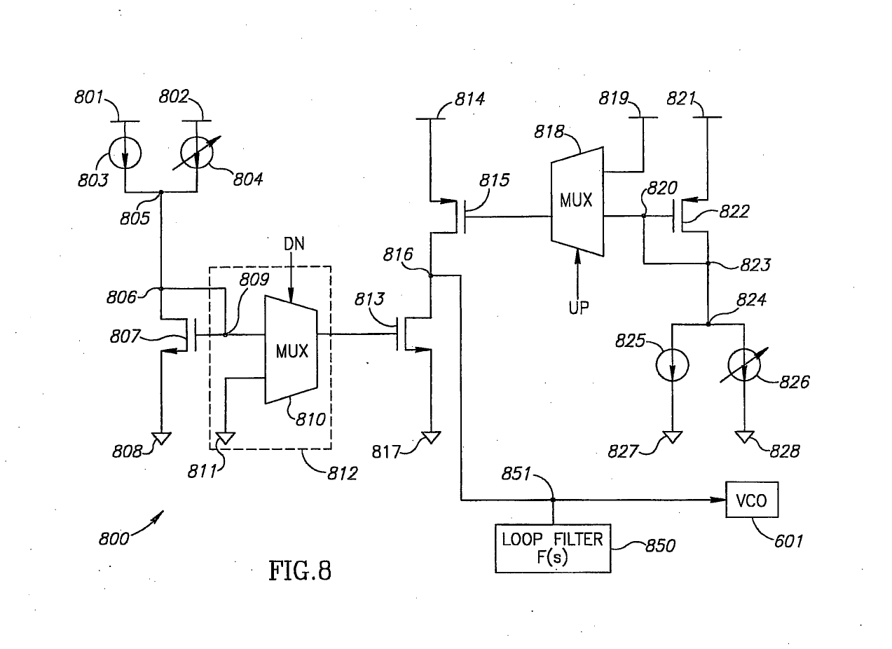

FIG. 8. schematically illustrates a low-dropout charge-pump circuit 800 with gain compensation, in accordance with exemplary embodiments of the invention. Circuit 800 may be included, for example, within oscillator 54 of FIG. 1.

Circuit 800 may include a voltage supply 801, which may provide a fixed current 803 to a node 805. A voltage supply 802 may provide a variable current 804 to node 805, which may be connected to a node 806. Node 806 may be connected to a drain terminal of a transistor 807, and to a node 809. A source terminal of transistor 807 may be connected to a sink 808, and a gate terminal of transistor 807 may be connected to node 809. Node 809 may be connected to multiplexer 810, which may be connected to a sink 811 and to a gate terminal of a transistor 813.

A source terminal of transistor 813 may be connected to a sink 817, and a drain terminal of transistor 813 may be connected to a node 816. Node 816 may provide output to node 851, which may be connected, for example, to loop filter 850 and/or to VCO 601 of FIG. 6. Loop filter 850 may include, for example, loop filter 603 and/or loop filter 604 of FIG. 6.

Node 816 may be connected to a drain terminal of a transistor 815, and a voltage supply 814 may be connected to a source terminal of transistor 815. A gate terminal of transistor 815 may be connected to a multiplexer 818, which may be connected to a voltage supply 819 and to a node 820. Node 820 may be connected to a node 823 and to a gate terminal of a transistor 822. A source terminal of transistor 822 may be connected to voltage supply 821, and a drain terminal of transistor 822 may be connected to node 823. Node 823 may be connected to a node 824. Node 824 may provide a fixed current 825 to a sink 827, and may provide a variable current 826 to a sink 828.

In some embodiments, currents 803, 804, 825 and/or 826 may provide gain compensation, and may allow, for example, tuning, adjusting and/or modifying a property of circuit 800, for example, the gain of circuit 800. In some embodiments, such tuning, adjustment and/or modification may be performed in relation to a gain of a VCO, e.g., the gain of VCO 601 of FIG. 6. Such modifications may increase and/or optimize, e.g., maximize, the total gain of circuit 800.

It would be appreciated by persons skilled in the art that circuit 800 may allow, for example, using one transistor 813 instead of a plurality of transistors to perform switching operations.

In some embodiments, the total current of circuit 800 may be switched into an output branch through node 816 and using switch transistors. In alternate embodiments, for example, in the exemplary embodiments of FIGS. 7 and 8, the total current of a charge-pump circuit may be switched into a “dummy” branch using switch transistors, as described below.

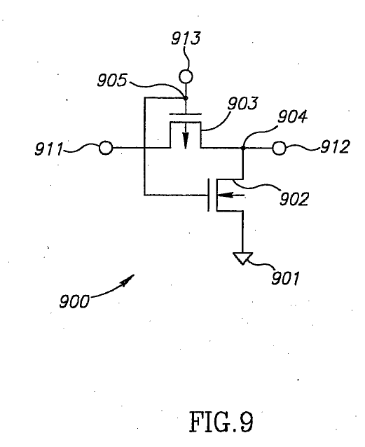

FIG. 9 schematically illustrates a sub-circuit 900, which may be an exemplary implementation of multiplexer 810 of FIG. 8. Sub-circuit 900 may include, for example, transistors 902 and 903, a sink 901, a node 904, and three terminals 911, 912 and 913.

In some embodiments, transistor 902 may include one or more NMOS varactors, e.g., one or more NMOS varactors similar to varactor 300 of FIG. 3. Transistor 903 may include one or more PMOS varactors, e.g., one or more PMOS varactors similar to varactor 400 of FIG. 4.

Terminal 911 may be connected to node 809 in circuit 800; terminal 912 may be connected to gate terminal of transistor 813 in circuit 800; and terminal 913 may receive a “down” signal.

It is noted that in some embodiments, sub-circuit 900 and/or multiplexer 810 may be used to allow, for example, implementation of circuit 800 on a plurality of stacks and/or hardware components.

In some embodiments, circuit 900 may be used as an exemplary implementation of multiplexer 818 of FIG. 8. In such case, terminal 913 may receive an “up” signal, instead of a “down” signal as received by multiplexer 810.

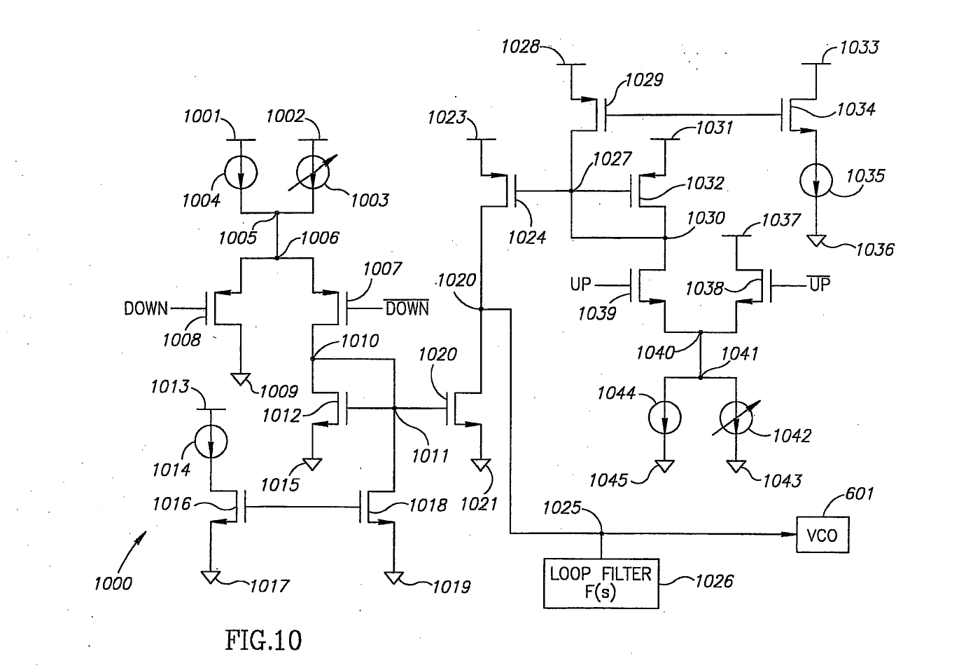

FIG. 10 schematically illustrates an enhanced charge-pump circuit 1000 with low drop-out gain compensation, in accordance with exemplary embodiments of the invention. Circuit 1000 may be included, for example, within oscillator 54 of FIG. 1.

In circuit 1000, a voltage supply 1001 may provide a fixed current 1004 to a node 1005, and a voltage supply 1002 may provide a variable current 1003 to node 1005. Node 1005 may be connected to a node 1006, which may be connected to a source terminal of a transistor 1007 and to a source terminal of a transistor 1008. A drain terminal of transistor 1008 may be connected to a sink 1009. A gate terminal of transistor 1008 may receive a “down” signal. A drain terminal of transistor 1007 may be connected to a node 1010, and a gate terminal of transistor 1007 may receive a “down bar” signal. Node 1010 may be connected to a node 1011 and to a drain terminal of a transistor 1012. A source terminal of transistor 1012 may be connected to a sink 1015, and a gate terminal of transistor 1012 may be connected to node 1011. A drain terminal of a transistor 1018 may be connected to node 1011, and a source terminal of transistor 1018 may be connected to a sink 1019. A gate terminal of transistor 1018 may be connected to a gate terminal of a transistor 1016. A source terminal of transistor 1016 may be connected to a sink 1017. A voltage supply 1013 may provide a fixed current 1014 to a drain terminal of transistor 1016.

Node 1011 may be connected to a gate terminal of a transistor 1020. A source terminal of transistor 1020 may be connected to a sink 1021, and a drain terminal of transistor 1020 may be connected to a node 1022. Node 1022 may provide output to a node 1025, which may be connected, for example, to loop filter 1026 and/or to VCO 601 of FIG. 6. Loop filter 1026 may include, for example, loop filter 603 and/or loop filter 604 of FIG. 6.

Node 1022 may be connected to a drain terminal of a transistor 1024, and source voltage supply 1023 may be connected to a source terminal of transistor 1024. A gate terminal of transistor 1024 may be connected to a node 1027. Node 1027 may be connected to a drain terminal of transistor 1029, and a voltage supply 1028 may be connected to a source terminal of transistor 1029. A gate terminal of transistor 1029 may be connected to a gate terminal of a transistor 1034. A voltage supply 1033 may be connected to a drain terminal of transistor 1034. A source terminal of transistor 1034 may provide a fixed current 1035 to a sink 1036.

Node 1027 may be connected to a node 1030, and to a gate terminal of a transistor 1032. A voltage supply 1031 may be connected to a source terminal of transistor 1032. A drain terminal of transistor 1032 may be connected to node 1030. Node 1030 may be connected to a drain terminal of transistor 1039. A gate terminal of transistor 1039 may receive an “up” signal. A source terminal of transistor 1039 may be connected to a node 1040. Node 1040 may be connected to a source terminal of a transistor 1038. A voltage supply 1037 may be connected to a drain terminal of transistor 1038. A gate terminal of transistor 1038 may receive an “up bar” signal. Node 1040 may be connected to a node 1041. Node 1041 may provide a fixed current 1044 to a sink 1045. Node 1041 may provide a variable current 1042 to a sink 1043.

In some embodiments, currents 1014 and 1035 may be used as a leak current path; transistors 1008 and 1039 may be used as a “dummy” branch; and transistors 1012 and 1020, as well as transistors 1024 and 1032, may be used as mirror sub-circuits. In an exemplary embodiment, the leak current path may be used, for example, to quickly turn-off the mirror sub-circuits when currents are switched into the “dummy” branch.

In some embodiments, natural time-constants (e.g., related to resistance and capacitance) of the mirror circuits may be large relative to a settling time of the mirror circuits. This may occur, for example, as a result of physical dimensions of various components in some implementations. To mitigate and/or avoid this, the leak current path may be used to prevent the loop-filter output from being altered during an “off” state of circuit 1000. This may allow, for example, a shorter settling time for nodes 1011 and 1027.

In some embodiments, the mirror transistors, e.g., transistors 1012 and 1020, as well as transistors 1024 and 1032, may be sized to require small overdrive voltage, for example, to support the current of circuit 1000. In some embodiments, this may result in wider swings at the output, without significant current output degradation.

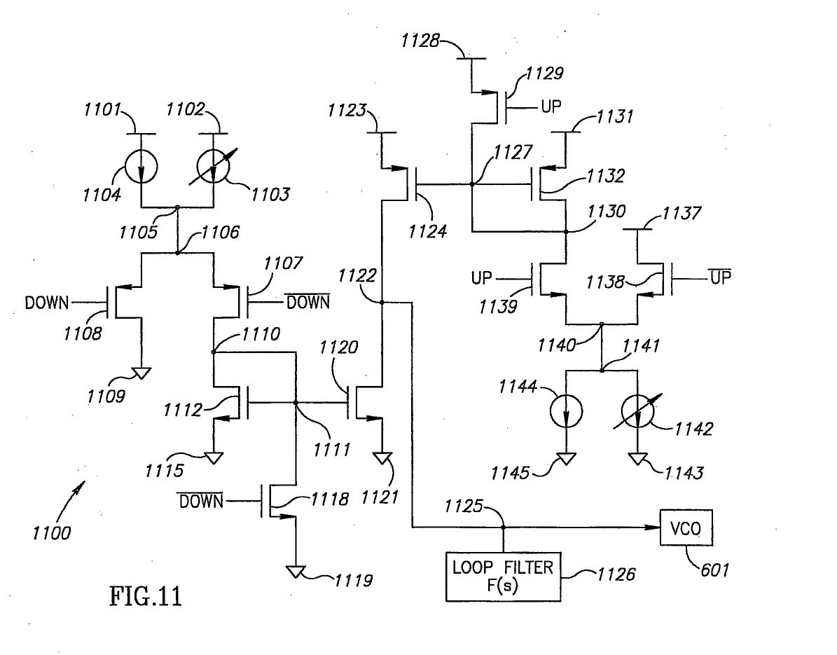

FIG. 11 schematically illustrates a charge-pump circuit 1100, which may include a mirror switch-off with enhanced gain compensation in accordance with exemplary embodiments of the invention. Circuit 1100 may be included, for example, within oscillator 54 of FIG. 1.

In circuit 1100, a voltage supply 1101 may provide a fixed current 1104 to a node 1105, and a voltage supply 1102 may provide a variable current 1103 to node 1105. Node 1105 may be connected to a node 1106, which may be connected to a source terminal of a transistor 1107 and to a source terminal of a transistor 1108. A drain terminal of transistor 1108 may be connected to a sink 1109. A gate terminal of transistor 1108 may receive a “down” signal. A drain terminal of transistor 1107 may be connected to a node 1110, and a gate terminal of transistor 1107 may receive a “down bar” signal. Node 1110 may be connected to a node 1111 and to a drain terminal of a transistor 1112. A source terminal of transistor 1112 may be connected to a sink 1115, and a gate terminal of transistor 1112 may be connected to node 1111. A drain terminal of a transistor 1118 may be connected to node 1111, and a source terminal of transistor 1118 may be connected to a sink 1119. A gate terminal of transistor 1118 may receive a “down bar” signal.

Node 1111 may be connected to a gate terminal of a transistor 1120. A source terminal of transistor 1120 may be connected to a sink 1121, and a drain terminal of transistor 1120 may be connected to a node 1122. Node 1122 may provide output to a node 1125, which may be connected, for example, to loop filter 1126 and/or to VCO 601 of FIG. 6. Loop filter 1126 may include, for example, loop filter 603 and/or loop filter 604 of FIG. 6.

Node 1122 may be connected to a drain terminal of a transistor 1124, and a voltage supply 1123 may be connected to a source terminal of transistor 1124. A gate terminal of transistor 1124 may be connected to a node 1127. Node 1127 may be connected to a drain terminal of transistor 1129, and a voltage supply 1128 may be connected to a source terminal of transistor 1129. A gate terminal of transistor 1129 receive an “up” signal.

Node 1127 may be connected to a node 1130, and to a gate terminal of a transistor 1132. A voltage supply 1131 may be connected to a source terminal of transistor 1132. A drain terminal of transistor 1132 may be connected to node 1130. Node 1130 may be connected to a drain terminal of transistor 1139. A gate terminal of transistor 1139 may receive an “up bar” signal. A source terminal of transistor 1139 may be connected to a node 1140. Node 1140 may be connected to a source terminal of a transistor 1138. A voltage supply 1137 may be connected to a drain terminal of transistor 1138. A gate terminal of transistor 1138 may receive an “up bar” signal. Node 1140 may be connected to a node 1141. Node 1141 may provide a fixed current 1144 to a sink 1145. Node 1141 may provide a variable current 1142 to a sink 1143.

In some embodiments, transistor 1118 may be used as a leak current path; transistors 1108 and 1138 may be used as a “dummy” brunch; and transistors 1112 and 1120, as well as transistors 1124 and 1132, may be used as mirror sub-circuits. In an exemplary embodiment, the leak current path may be used, for example, to quickly turn-off the mirror sub-circuits when currents are switched into the “dummy” branch.

In some embodiments, natural time-constants (e.g., related to resistance and capacitance) of the mirror circuits may be large relative to a settling time of the mirror circuits. This may occur, for example, as a result of physical dimensions of various components in some implementations. To mitigate and/or avoid this, the leak current path may be used to prevent the loop-filter output from being altered during the off-state of circuit 1100. This may allow, for example, a shorter settling time for nodes 1111 and 1127.

In some embodiments, the mirror transistors (e.g., transistors 1112 and 1120, as well as transistors 1124 and 1132) may be sized to require small overdrive voltage, for example, to support the current of circuit 1100. In some embodiments, this may result in wider swings at the output, without significant current output degradation.

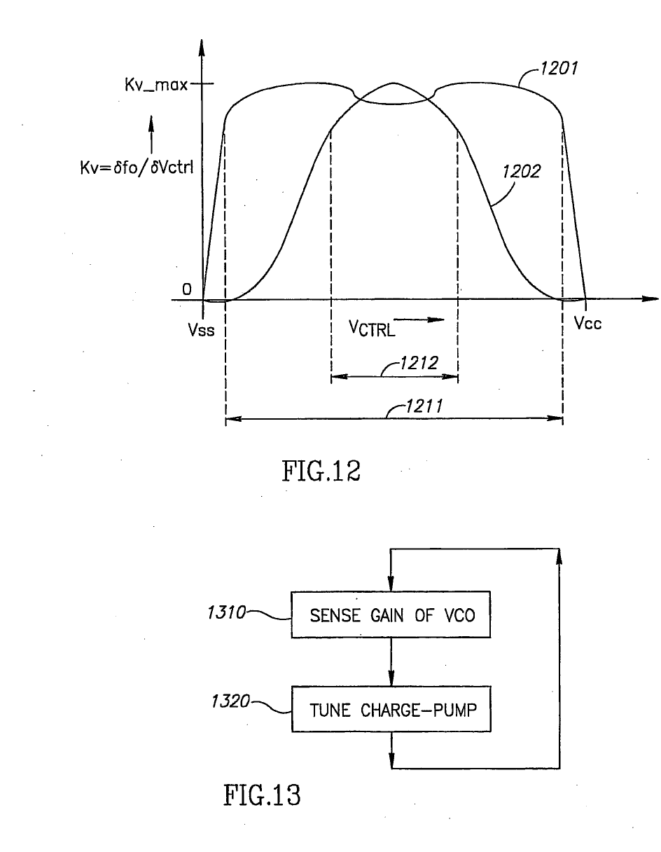

FIG. 12 schematically illustrates a graph depicting gain in accordance with an exemplary embodiment of the invention. Each of lines 1201 and 1202 indicates loop-gain as a function of control voltage in a charge-pump in accordance with an exemplary embodiment of the invention.

Line 902 may result from using a tunable charge-pump in accordance with some embodiments of the invention, allowing an un-compensated tuning range 912.

Line 901 may result from using a tunable charge-pump in conjunction with increasing the tunable range of the charge-pump, in accordance with some embodiments of the invention, for example, from using circuit 600 of FIG. 6, allowing a wide compensated tuning range 911.

In accordance with an exemplary embodiment of the invention, sensor/detector 666 of FIG. 6 may sense the gain drops of line 902. This may be performed, for example, based on a control voltage. Accordingly, sensor/detector 666 may operate charge-pump 610 to achieve gain compensation.

It is noted that other graphs and/or lines may represent loop gain of various embodiments of the invention.

In some conventional circuits, the maximum effective tuning voltage of a circuit may be equal or related to V_{cc}−2*V_{dsat}, and the minimum effective tuning voltage may be equal or proportional to Vₛₛ+2*V_{dsat}, wherein V_{cc} is the supply voltage of the circuit, Vₛₛ is a ground voltage, and V_{dsat} is a saturation voltage. It will be appreciated by persons skilled in the art that embodiments of the invention may allow a reduction or a significant reduction in the value of V_{dsat}, and may thus achieve a larger capacitance range, effective tuning range and/or gain. Additionally or alternatively, it will be appreciated by persons skilled in the art that, in embodiments of the invention, the maximum effective tuning voltage of a circuit may be equal or proportional to V_{cc}−V_{dsat} and the minimum tuning voltage of a circuit may be equal or proportional to Vₛₛ+V_{dsat}, thus allowing a further increase in capacitance range, tuning range and/or gain.

Some embodiments of the invention may be implemented by software, by hardware, or by any combination of software and/or hardware as may be suitable for specific applications or in accordance with specific design requirements. Embodiments of the invention may include units and/or sub-units, which may be separate of each other or combined together, in whole or in part, and may be implemented using specific, multi-purpose or general processors, or devices as are known in the art. Some embodiments of the invention may include buffers, registers, storage units and/or memory units, for temporary or long-term storage of data or in order to facilitate the operation of a specific embodiment

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

What is claimed is:

1. A varactor comprising:
a channel having a length significantly larger than a minimum operable length of said channel.

2. The varactor of claim 1, wherein the length of the channel is at least thirty percent larger than said minimum length.

3. The varactor of claim 1, wherein the length of the channel is at least fifty percent larger than said minimum length.

4. The varactor of claim 1, wherein the length of the channel is not more than one hundred percent larger than the minimum operable length of the channel.

5. The varactor of claim 1, wherein the varactor comprises a Positive-charged-carrier Metal-Oxide-Semiconductor varactor.

6. The varactor of claim 1, wherein the varactor comprises a Negative-charged-carrier Metal-Oxide-Semiconductor varactor.

7. The varactor of claim 1, comprising an accumulation mode varactor.

8. The varactor of claim 1, comprising an inversion mode varactor.

9. An apparatus comprising:
an oscillator having a tunable charge-pump.

10. The apparatus of claim 9, comprising a gain tuner to tune the gain of said tunable charge-pump.

11. The apparatus of claim 10, wherein said gain tuner is able to tune the gain of said tunable charge-pump in response to a property of said oscillator.

12. The apparatus of claim 11, wherein said gain tuner is able to tune the gain based on a value related to a gain of at least a portion of said oscillator.

13. The apparatus of claim 12, wherein said gain tuner is able to tune the gain based on a value related to a gain of a voltage controlled oscillator of said oscillator.

14. The apparatus of claim 12, comprising a detector to detect said value.

15. The apparatus of claim 14, wherein said detector is able to substantially continuously detect said value.

16. The apparatus of claim 9, wherein said tunable charge-pump comprises at least one tunable current source to modify the gain of said tunable charge-pump.

17. The apparatus of claim 9, wherein the tunable charge-pump comprises at least one dummy branch to receive current.

18. The apparatus of claim 9, wherein the tunable charge-pump comprises at least one switch transistor to switch the charge-pump current.

19. The apparatus of claim 9, wherein the tunable charge-pump comprises at least two mirror sub-circuits.

20. The apparatus of claim 9, wherein the tunable charge-pump comprises a leak current path to turn-off a mirror sub-circuit.

21. The apparatus of claim 9, wherein the tunable charge-pump is differential.

22. A wireless communication device comprising:
a dipole antenna to send and receive wireless signals; and
a varactor comprising a channel having a length significantly larger than a minimum operable length of said channel.

23. The wireless communication device of claim 22, wherein the length of said channel is at least thirty percent larger than said minimum length.

24. The wireless communication device of claim 22, wherein the length of said channel is at least fifty percent larger than said minimum length.

25. The wireless communication device of claim 22, wherein the length of said channel is not more than one hundred percent larger than the minimum operable length of said channel.

26. A wireless communication device comprising:
a dipole antenna to send and receive wireless signals; and
an oscillator having a tunable charge-pump.

27. The wireless communication device of claim 26, comprising a gain tuner to tune the gain of said tunable charge-pump.

28. The wireless communication device of claim 27, wherein said gain tuner is able to tune the gain of said tunable charge-pump in response to a property of said oscillator.

29. The wireless communication device of claim 28, wherein said gain tuner is able to tune the gain based on a value related to a gain of at least a portion of said oscillator.

30. The wireless communication device of claim 26, wherein said tunable charge-pump comprises at least one tunable current source to modify the gain of said tunable charge-pump.

31. The wireless communication device of claim 26, wherein the tunable charge-pump comprises at least one dummy branch to receive current.

32. The wireless communication device of claim 26, wherein said tunable charge-pump comprises a leak current path to turn-off a mirror sub-circuit of said tunable charge-pump.

33. The wireless communication device of claim 26, wherein the tunable charge-pump is differential.

34. A method comprising:
tuning a gain of a charge-pump of an oscillator.

35. The method of claim 34, wherein tuning the gain comprises tuning the gain based on a value related to a gain of at least a portion of said oscillator.

36. The method of claim 35, wherein tuning the gain comprises tuning the gain based on a value related to a gain of a voltage controlled oscillator of said oscillator.

37. The method of claim 36, comprising detecting said value.

38. The method of claim 37, comprising substantially continuously detecting said value.

39. The method of claim 34, wherein tuning the gain comprises transferring current to a dummy branch.

40. The method of claim 34, wherein tuning the gain comprises turning off at least one mirror sub-circuit.

41. The method of claim 34, wherein tuning the gain comprises tuning a gain of a differential charge-pump.
